(19) United States
(12) Patent Application Publication
(10) Pub. No.: US 2015/0049342 A1
(43) Pub. Date: Feb. 19, 2015

(54) SURFACE LIGHT-EMITTING LASER AND OPTICAL COHERENCE TOMOGRAPHIC IMAGING APPARATUS HAVING THE SAME

(71) Applicant: CANON KABUSHIKI KAISHA, Tokyo (JP)

(72) Inventor: Yasuhiro Nagatomo, Kawasaki-shi (JP)

(21) Appl. No.: 14/459,169

(22) Filed: Aug. 13, 2014

(30) Foreign Application Priority Data
Aug. 19, 2013 (JP) 2013-169607

(51) Int. Cl. H01S 5/183; G01B 9/02; H01S 5/187

(52) U.S. Cl. CPC H01S 5/18361; H01S 5/187; G01B 9/02091
USPC 356/479; 372/99

(57) ABSTRACT

A surface light-emitting laser comprising an upper reflector, a lower reflector, and an active layer interposed therebetween, wherein when an optical distance between the upper reflector and the lower reflector is referred to as a first distance, and an optical distance between the lower reflector and the active layer is referred to as a second distance, positions of at least selected two of a group including the upper reflector, the lower reflector, and the active layer are changed so that the ratio between the first distance and the second distance is maintained within a range of ±25% from a certain value.

### BACKGROUND OF THE INVENTION

1. Field of the Invention

This disclosure relates to a surface light-emitting laser and an optical coherence tomographic imaging apparatus having the same.

2. Description of the Related Art

In recent years, wavelength variable lasers in which an oscillation wavelength is variable are actively researched and developed because application to various fields such as communication, sensing, imaging, and the like.

As one of various types of wavelength variable lasers, a structure configured to control a lasing wavelength of a vertical resonator type surface light-emitting laser (VCSEL) by MEMS (Micro Electro Mechanical System) technology, a so-called MEMS-VCSEL, is known.

A VCSEL is generally includes a pair of reflectors such as distribution Bragg reflectors (DBR) and an active layer interposed therebetween, and is configured to lase at a wavelength depending on a cavity length determined by an optical distance between the reflectors. The MEMS-VCSEL is configured vary the lasing wavelength by varying the cavity length by mechanically moving one of the reflectors (Specification of U.S. Pat. No. 5,291,502) in position.

However, a threshold gain of lasing, in the VCSEL of the related art as in U.S. Pat. No. 5,291,502, is increased at wavelength far from a central wavelength.

### SUMMARY OF THE INVENTION

This disclosure provides a surface light-emitting laser configured to restrain an increase in threshold gain of lasing at wavelengths far from a central wavelength.

A laser of this disclosure is a surface light-emitting laser including an upper reflector, a lower reflector, and an active layer interposed therebetween, wherein

when an optical distance between the upper reflector and the lower reflector is referred to as a first distance, and an optical distance between the lower reflector and the active layer is referred to as a second distance, positions of at least selected two of a group including the upper reflector, the lower reflector, and the active layer are changed so that the ratio between the first distance and the second distance is maintained within a range of ±25% from a certain value.

An apparatus of this disclosure is an optical coherence tomographic imaging apparatus including a light source unit configured to vary a wavelength of light, an interference optical system configured to split light from the light source unit into an illuminated light beam to be radiated on an object and a reference light beam to cause a reflected light of the light beam radiated on the object and an interfering light beam by the reference light beam to be generated, a light detecting unit configured to receive the interfering light beam, and an information obtaining unit configured to process a signal from the light detecting unit and obtain information on the object, wherein the light source unit is the surface light-emitting laser, described above.

Further features of the present invention will become apparent from the following description of exemplary embodiments with reference to the attached drawings.

### BRIEF DESCRIPTION OF THE DRAWINGS

FIG. 1 is a schematic cross-sectional view illustrating a structure of a VCSEL according to an embodiment of this disclosure.

FIG. 2 is an explanatory schematic view illustrating a light intensity distribution in a configuration in which a surface light-emitting laser according to the embodiment of this disclosure is applied.

FIG. 3 is a graph for explaining an effect of the surface light-emitting laser according to the embodiment of this disclosure.

FIG. 4 is a graph for explaining an effect of the surface light-emitting laser according to the embodiment of this disclosure.

FIG. 5 is an explanatory schematic view illustrating a light intensity distribution in a configuration in which the surface light-emitting laser according to the embodiment of this disclosure is applied.

FIG. 6 is a graph for explaining a range in which the effect of the surface light-emitting laser according to the embodiment of this disclosure is obtained.

FIG. 7 is a schematic cross-sectional view illustrating a structure of a VCSEL according to Example 1 of this disclosure.

FIGS. 8A and 8B are schematic views illustrating a structure of a VCSEL according to Example 2 of this disclosure.

FIG. 9 is a graph for explaining a feature of a reflector according to Example 2 of this disclosure.

FIG. 10 is a schematic cross-sectional view illustrating a structure of a MEMS-VCSEL of the related art.

FIG. 11 is a graph for explaining a situation that the MEMS-VCSEL of the related art has.

FIG. 12 is a graph for explaining a situation that the MEMS-VCSEL of the related art has.

FIG. 13 is an explanatory drawing illustrating an example in which a wavelength variable surface light-emitting laser of the embodiment of this disclosure is used in a light source unit of an OCT.

### DESCRIPTION OF THE EMBODIMENTS

An embodiment of this disclosure will be described.

First of all, a situation that a MEMS-VCSEL of the related art has will be described.

FIG. 10 illustrates a schematic cross-sectional view of a general MEMS-VCSEL.

The MEMS-VCSEL in FIG. 10 is formed of compound semiconductor based on GaAs, and is designed to have a central wavelength of 850 nm so that the wavelength is variable around the central wavelength. A configuration including an active layer 1020 and a space portion 1030 interposed between an upper reflector 1000 and a lower reflector 1010 is arranged on a substrate 1050. A distribution Bragg reflector (DBR) formed of multilayer films is used as the reflector.

The length of the space portion 1030 is changed by moving the upper reflector 1000 in the upward and downward directions, whereby a cavity length is changed, correspondingly. Accordingly, a resonant wavelength varies, so that a lasing wavelength can be changed.

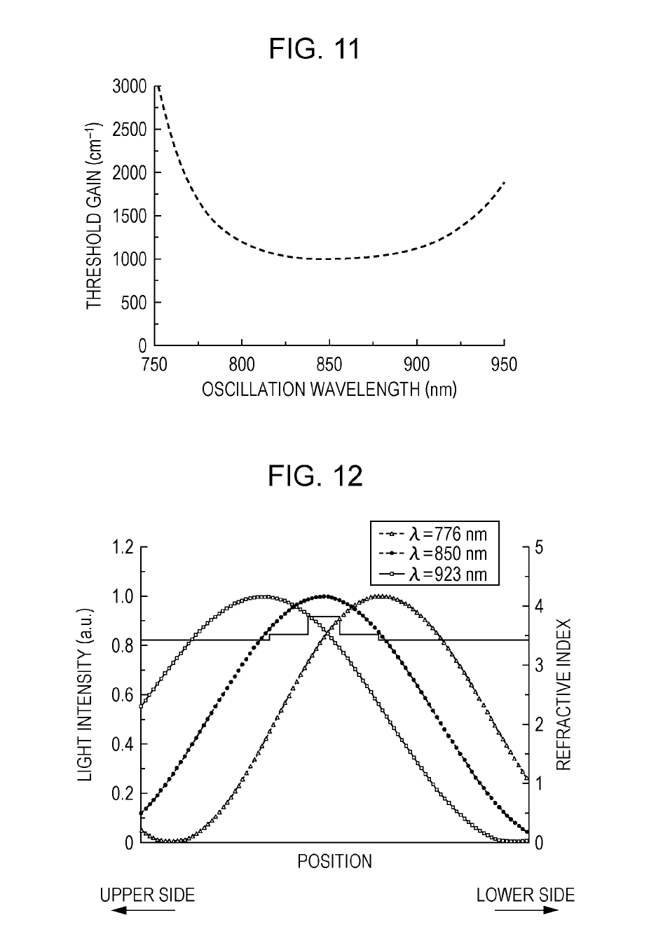

FIG. 11 illustrates an example of calculation of a relationship between the lasing wavelength and the gain (threshold gain) required for lasing in the MEMS-VCSEL illustrated in FIG. 10.

In this calculation, the active layer is formed of a single quantum well layer formed of InGaAs having a thickness of 8 nm, and the gain per unit length required for the lasing was calculated on an assumption that a uniform gain is created uniformly in the active layer.

In this calculation, an influence of a mode hop was ignored, and a vertical mode of the same order was calculated.

From the result of calculation in FIG. 11, it is seen that the threshold gain is the smallest around the wavelength of 850 nm, and the threshold gain is increased as it goes farther therefrom. It means that a larger gain is used in order to achieve lasing at wavelengths far from the central wavelength.

Since the magnitude of the gain obtained realistically in the active layer is limited, the threshold gain exceeds the gain obtained in the active layer at wavelength far from the central wavelength to some extent, so that the lasing is disabled. This may hinder the wavelength variable range of the MEMS-VCSEL from becoming a large bandwidth.

The reason why the threshold gain is increased as it goes farther from the central wavelength will be described.

The VCSEL is configured so that the position where the light intensity is strong, that is, positions of antinodes of light standing wave and the position of the active layer are aligned within the resonator. It helps to maximize mutual action between the active layer and the light and amplify the light effectively.

However, in the MEMS-VCSEL of the related art, it is difficult to align the positions of antinodes of light standing wave and the position of an active layer.

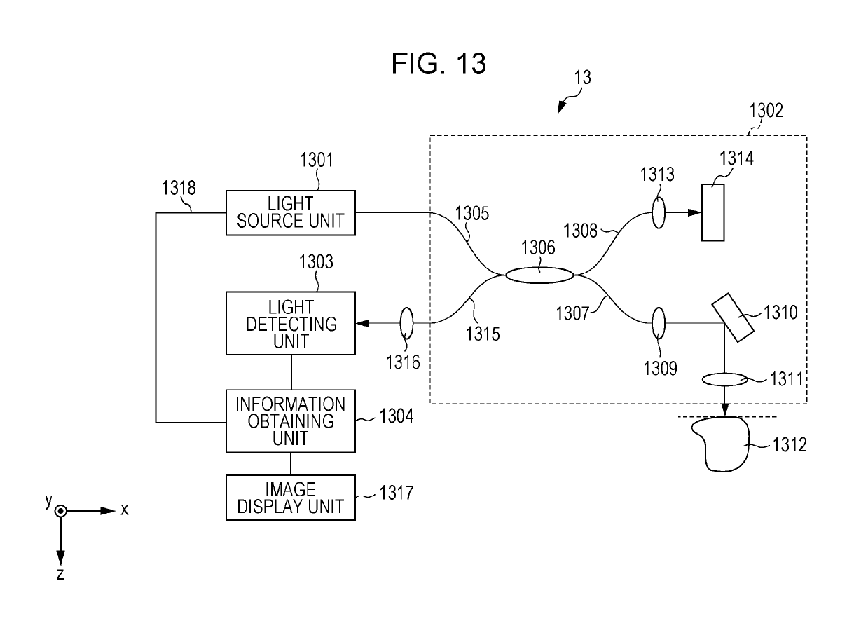

FIG. 12 illustrates a wavelength dependency of a light distribution around the active layer of the MEMS-VCSEL illustrated in FIG. 10. In the graph, the refractive index is shown by a solid line, and the light distribution is shown by a line with symbols.

FIG. 12 and FIG. 10 illustrate arrangements different in orientation by 90°. The left side of FIG. 12 corresponds to the upper side of FIG. 10, and the right side of FIG. 12 corresponds to the lower side of FIG. 10.

A portion of the graph in FIG. 12 having the highest refractive index corresponds to a quantum well layer, which is an active layer.

A case where the light distribution is illustrated by calculating at three lasing wavelengths λ of 776 nm, 850 nm, 923 nm.

The MEMS-VCSEL in FIG. 10 is designed so that the positions of antinodes of light standing wave and the active layer match at a central wavelength of 850 nm, so that a positional relationship as designed is achieved.

In order to change the lasing wavelength of the MEMS-VCSEL in FIG. 10, the position of the upper reflector 1000 is changed to change the length of the space portion 1030. Specifically, when the length of the space portion is reduced, the cavity length is reduced correspondingly, so that the lasing wavelength is changed toward the short wavelength side. In contrast, when the length of the space portion is increased, the cavity length is increased correspondingly, so that the lasing wavelength is changed toward the long wavelength side.

The light distribution varies in accordance with variations in cavity length and corresponding variations in lasing wavelength.

In FIG. 12, at 923 nm, which is a wavelength longer than the central wavelength, the positions of antinodes of light standing wave is deviated to the side closer to the space portion when viewed from the active layer, in other words, upward. In contrast, at 776 nm, which is a wavelength shorter than the central wavelength, the positions of antinodes of light standing wave are deviated to the side far from the space portion, in other words, downward.

In this manner, with the MEMS-VCSEL of the related art, the positions of antinodes of light standing wave and the position of an active layer are deviated at wavelengths other than the central wavelength.

If the positions of antinodes of light standing wave and the position of an active layer are deviated, the mutual action of the active layer and light is weakened. Therefore, in order to achieve a light amplification effect, the active layer is to have a larger gain.

The larger the deviation of the wavelength from the central wavelength, the above-described effect is increased.

It seems that the above-described situations are elements that cause the threshold gain to increase as it goes farther from the central wavelength as illustrated in FIG. 11.

Inventors of this disclosure has found that the deviation of the position of antinodes of light standing wave and the position of an active layer depending on the wavelength is a reason why the threshold gain depends on the wavelength by an analysis illustrated in FIG. 12.

The surface light-emitting laser of the embodiment is capable of restraining an increase in wavelength dependency of the threshold gain, more specifically, an increase in threshold gain of the lasing in wavelengths far from the central wavelength.

The surface light-emitting laser (VCSEL) of the embodiment of this disclosure will be described in detail. In the following description, the surface light-emitting laser may be referred to as VCSEL or a wavelength variable surface light-emitting layer may be referred to as a wavelength variable surface light-emitting laser.

First of all, terms used in this specification are defined.

In this specification, the substrate side of a laser element is defined as the lower side, and the side opposite to the substrate is defined as the upper side.

In this specification, the term “central wavelength” is used in a sense of a wavelength at a center of a wavelength range of the laser beam that the surface light-emitting laser can emit.

In other words, the term “central wavelength” means a wavelength at a center between the shortest wavelength and the longest wavelength which allows lasing therefrom. The wavelengths at which lasing is enabled are determined depending on a variation width of the cavity length, a reflecting band frequency of the reflector, a gain band of the active layer, and the like. Basically, at the time of designing, the central wavelength is set, and configurations of the respective elements are determined correspondingly.

When describing the distance in this specification, the distance means an optical distance, which is a product of the actual distance and the refractive index unless otherwise specifically described.

In a configuration in which this disclosure is applied, the relative position between the antinodes of light standing wave and the active layer is hardly deviated even though the lasing wavelength varies, so that an increase in threshold gain may be suppressed.

Specifically, by controlling the positional relationship between the active layer with respect to the upper reflector and the lower reflector arranged so as to interpose the active layer therebetween with a control unit, a configuration in which the active layer and the positions of antinodes of light standing wave are hardly deviated is achieved. It is possible to use either a plurality of control units or a single control unit in order to vary positions in the directions of optical paths of the upper reflector, the lower reflector, and the active layer.

Controlling adequately here means to vary the positions of at least two elements selected from a group including the upper reflector, the lower reflector, and the active layer adequately. Specifically, if the optical distance between the upper reflector and the active layer is defined as a first distance, and the optical distance between the lower reflector and the active layer is defined as a second distance, the position is controlled so that the ratio between the first distance and the second distance is kept at a certain value. Also, control of the position is done to maintain the above-descried ratio within the range of ±25% from a certain value. The position is controlled so that the ratio between the first distance and the second distance may be maintained within a range of ±20% from a certain value and, or within a range of ±5%.

In this specification, the optical distance between the upper reflector and the lower reflector is referred to as the first distance, and the optical distance between the lower reflector and the active layer is referred to as the second distance.

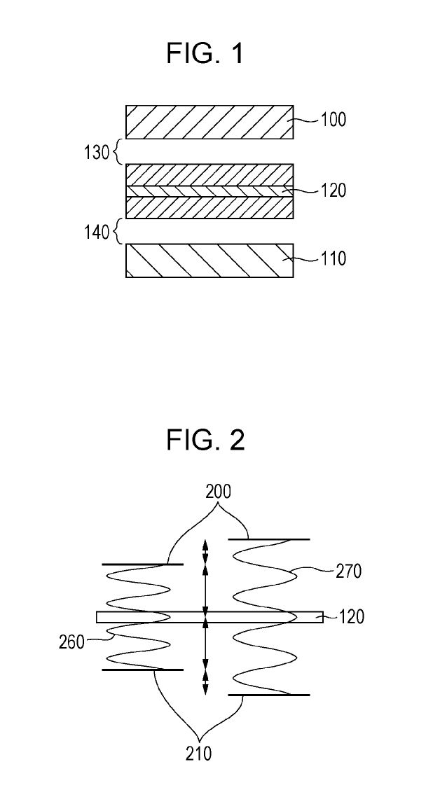

A simple example of the wavelength variable surface light-emitting laser according to the embodiment will be described with reference to FIG. 1.

An upper reflector 100, an upper space portion 130, an active layer 120, a lower space portion 140, and a lower reflector 110 are arranged in this order from the top.

The thicknesses of the upper space portion 130 and the lower space portion 140 are equal, and the upper reflector 100 and the lower reflector 110 are arranged with the active layer 120 interposed therebetween at the same distance.

An area interposed between the upper reflector 100 and the lower reflector 110 corresponds to a resonator, and a light standing wave is formed at the resonant wavelength.

In the embodiment, an example in which distribution Bragg reflectors (DBR) formed of a multi-layer film are used as the upper reflector and the lower reflector.

FIG. 2 is a schematic drawing for explaining a light intensity distribution in the structure illustrated in FIG. 1.

In order to simplify the drawing, in FIG. 2, illustration of structure other than an end surface 200 of the upper reflector, an end surface 210 of the lower reflector, and the active layer 120 is omitted.

The light intensity distribution illustrated here includes examples of a light intensity distribution 260 at the first wavelength and a light intensity distribution 270 at a second wavelength, which is longer than the first wavelength.

The light intensity distribution in FIG. 2 is schematically illustrated, and the fact that the light intensity is higher as respective curves move rightward, and the light intensity is low as it goes leftward. In other words, the positions where the light intensity projects rightward correspond to the positions of antinodes of light standing wave, and positions projecting leftward correspond to the positions of antinodes.

When focusing on the light intensity distribution 260 of the first wavelength, there are a plurality of the antinodes of light standing wave, and one of those is positioned at the same distance from the upper reflector and from the lower reflector, that is, at a center of the resonator. Since the active layer is arranged at the central position of the resonator, positions of one of the antinodes of light standing wave and the active layer overlap with each other in position.

Here, a case where the resonant wavelength is changed from the first wavelength to the second wavelength will be considered. In order to change the resonant wavelength to the second wavelength, which is longer than the first wavelength, the position of the reflector is to be positionally deviated to elongate the cavity length.

In this case, the optical distance of the upper reflector and the lower reflector from the active layer can be maintained equidistantly by displacing the upper reflector and the lower reflector are deviated so that amounts of displacement from the positions at the first wavelength are the same and the directions of displacement are opposite. Consequently, a state in which one of the antinodes of light standing wave and the position of an active layer overlap with each other at the center of the resonator is achieved as illustrated as the light intensity distribution 270.

In this manner, even when the cavity length is changed, the state in which one of the antinodes of light standing wave and the position of the active layer overlap with each other at the central position of the resonator is achieved by controlling the resonator structure in upper and lower symmetry with respect to the active layer.

Consequently, an increase in threshold gain caused by the positional deviation between the antinodes of light standing wave and the active layer relative to each other may be reduced.

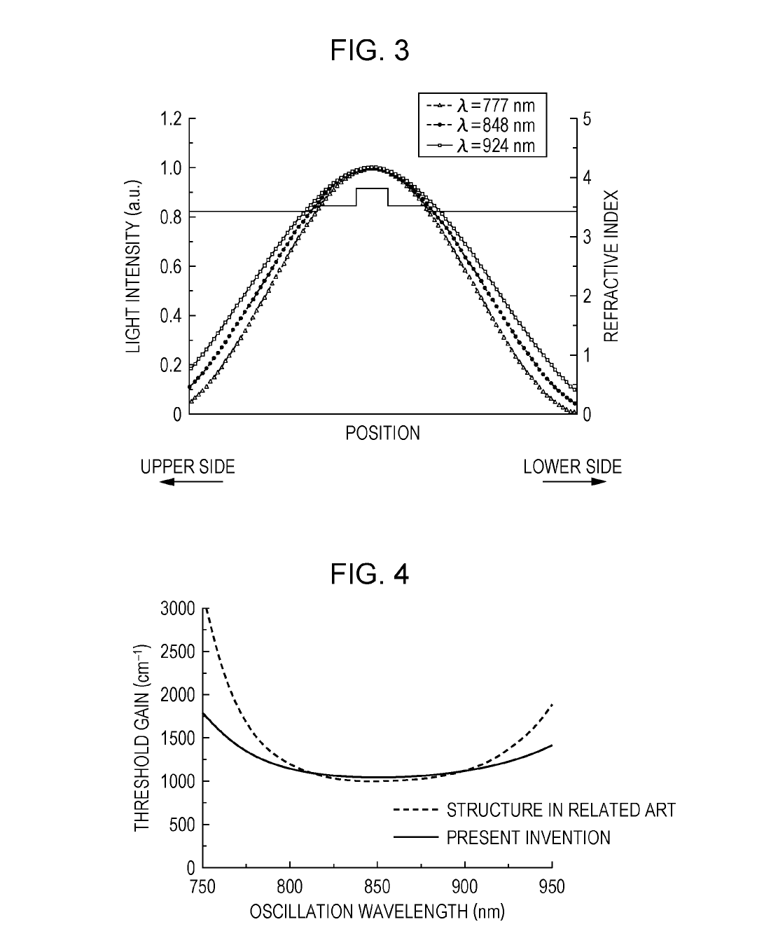

An effect of the wavelength variable surface light-emitting laser according to the embodiment will be described on the basis of the result of calculation. FIG. 3 illustrates an example of calculation of the light distribution near the active layer of the wavelength variable surface light-emitting laser of the present description will be described.

In the graph, the refractive index is shown by a solid line, and the light distribution is shown by a line with symbols.

Illustrations in FIG. 3 and FIG. 12 are shown in the same direction.

A portion of the graph having the highest refractive index corresponds to a quantum well layer, which is an active layer in the graph illustrated in FIG. 3 in the same manner as FIG. 12.

The light distribution is illustrated at three cases of 777 nm, 848 nm, 924 nm, which are substantially the same wavelength as those illustrated in FIG. 12.

As described with reference to FIG. 12, in the VCSEL of the related art, if the oscillation wavelength varies, the positions of antinodes of light standing wave and the active layer are disadvantageously deviated.

In contrast, as is apparent from FIG. 3, with the wavelength variable surface light-emitting laser of the embodiment, even though the oscillation wavelength varies, the relative positional deviation between the antinodes of light standing wave and the active layer can hardly occur. Therefore, it seems that an increase in threshold gain caused by the positional deviation cannot be occurred easily.

FIG. 4 shows a result of calculation of comparison of the threshold gain between the VCSEL to which the technology of the related art is applied and the wavelength variable surface light-emitting laser of the embodiment.

Both are the MEMS-VCSELs designed so that the wavelength is variable near a central wavelength of 850 nm.

The wavelength variable surface light-emitting laser of the embodiment shows a gentle increase in threshold gain at wavelength far from the central wavelength in comparison with the related art.

In this manner, it is shown that the wavelength variable surface light-emitting laser of the embodiment has a structure in which the increase in threshold gain of lasing can hardly occur at wavelength far from the central wavelength.

As is apparent from FIG. 4, the increase in threshold gain cannot be restrained completed even though the wavelength variable surface light-emitting laser of the embodiment is used. However, it is caused by the fact that the reflecting band frequency of the DBR is designed for wavelengths near 850 nm, and hence a reflectance ratio is lowered as is go farther from 850 nm. By using the wavelength variable surface light-emitting laser of the embodiment, the increase in threshold gain caused by the positional deviation described above is restrained, which appears as a differential in comparison with the related art.

The structure which is in upward and downward symmetry with respect to the active layer has been described thus far as a simple example, the structures in which the effect of this disclosure is achieved is not limited thereto. Furthermore, the ratio between the first distance and the second distance defined above is kept at a certain value.

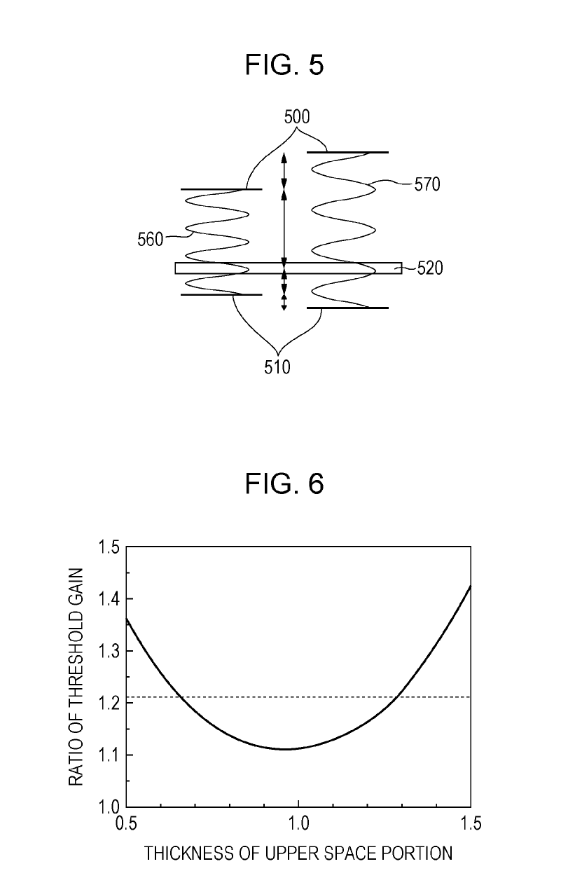

Description about keeping the ratio between the first distance and the second distance at a certain distance will be described with reference to FIG. 5.

FIG. 5 is a schematic drawing for describing the light intensity distribution in the wavelength variable surface light-emitting laser according to the embodiment, which has a different configuration from that in FIG. 1.

FIG. 5 is a schematic illustration in the same manner as FIG. 2, and structure other than those of an end surface 500 of the upper reflector, an end surface 510 of the lower reflector, and an active layer 520 are omitted.

The light intensity distribution is illustrated schematically as in FIG. 2, and an example of a light intensity distribution 560 at the first wavelength and a light intensity distribution 570 at the second wavelength longer than the first wavelength is illustrated.

When focusing on the light intensity distribution 560 at the first wavelength, there are a plurality of antinodes of light standing wave, and the active layer 520 is arranged at a position overlapping with one of those. The ratio between the optical distance (first distance) from the upper reflector 500 and the optical distance (the second distance) from the lower reflector 510 of the active layer 520 is defined as 3:1.

Here, a case where the wavelength is changed from the first wavelength to the second wavelength is considered. In order to change the resonant wavelength to the second wavelength, which is longer than the first wavelength, the position of the reflector is to be positionally deviated to elongate the cavity length. In this case, if the upper reflector and the lower reflector are displaced so that the amount of deviation from the position at the first wavelength becomes 3:1 and the directions are opposite, the ratio of the optical distances from the active layer can be maintained at 3:1. Consequently, as shown as the light intensity distribution 570, a state in which positions of one of the antinodes of light standing wave and the active layer overlap with each other may be maintained.

Here, the ratios between the optical distances from the respective active layers of the respective reflectors are both 3:1 correspondingly.

In this manner, by controlling the optical distances from the upper and lower reflectors and the ratio in amount of deviation of the upper and lower reflectors in one-to-one correspondence, the state in which positions of one of the antinodes of light standing wave and the active layer overlap with each other may be maintained.

Consequently, an increase in threshold gain caused by the positional deviation between the antinodes of light standing wave and the active layer relative to each other may be reduced.

Although an example of the configuration in which the upper and lower reflectors are moved and the position of the active layer is fixed has been described, a configuration in which one of the upper and lower reflectors is fixed and the other reflector and the active layer are moved is also applicable. In this case as well, it is important to control so that the optical distance (the first distance) between the upper reflector and the active layer and the optical distance (second distance) between the lower reflector and the active layer keeps a certain ration.

When determining the optical distance from the reflector to the active layer in the wavelength variable surface light-emitting laser of the embodiment, the optical path lengths of all of the layers located therebetween including not only the space portion, but also an antireflection film and a clad layer are to be considered.

In the case where the phase is changed when the light is reflected from the upper and lower reflectors, an effective optical path length considering the variations is to be considered.

In the case where the wavelength sweeping is performed continuously in the wavelength variable surface light-emitting laser according to the embodiment, the respective reflectors may be vibrated (displaced) at a certain frequency. The certain frequency may be a resonant frequency, or may be other frequencies.

In that case, the wavelength variable surface light-emitting laser according to the embodiment is achieved by causing the upper reflector and the lower reflector to vibrate (be displaced) so that the amplitudes of the respective reflectors correspond to the ratio between the optical distances from the respective reflectors to the active layer. In the case of the structure in upper and lower symmetry with respect to the active layer, the upper reflector and the lower reflector are vibrated (displaced) at the same amplitude.

In this specification, vibrating (displacing) so that the direction of the displacement becomes the opposite is expressed as vibrating (displacing) in the opposite phase.

In the wavelength variable surface light-emitting laser according to the embodiment, in order to control the positional relationship among the active layer and the upper and lower reflectors arranged with the active layer interposed therebetween, a control unit configured to control the positions of the respective components may be provided. In the wavelength variable surface light-emitting laser according to the embodiment, the upper and lower reflectors are not specifically limited as long as the reflectance ratio sufficient for the lasing is obtained. For example, a DBR formed of a dielectric material or a semiconductor multi-layer film, a metallic film, or a diffraction grating may be used.

However, as described above, the increase in threshold gain occurs also by the lowering of the reflectance ratio of the reflector as described above. When the reflecting band frequency of the reflector is narrow, the increase in threshold gain due to lowering of the reflectance ratio becomes dominant before the increase in threshold gain due to the positional deviation at wavelength far from the central wavelength becomes obvious. In other words, the significance of application of this disclosure becomes less.

Therefore, in order to achieve the effect of this disclosure clearly, the dielectric material DBR having a wide reflecting band frequency or a diffraction grating having a frequency structure of a sub wavelength which is referred to as HCG (High-Contrast Grating) is used.

In the wavelength variable surface light-emitting laser of the embodiment, an active layer used in general surface light-emitting lasers may be used as the active layer.

The thinner the active layer, the more sensitive for the positional deviation of the light distribution. Therefore, the effect of this disclosure obviously appears. A case where the active layer is composed of a single layer quantum well is a typical configuration.

In order to achieve the wavelength variable surface light-emitting laser according to the embodiment, the ratio between the first distance and the second distance is to be kept at a certain value.

However, even though the certain value is not strictly maintained, if the ratio falls within a certain range therefrom, the positional deviation is reduced in comparison with the structure of the related art, so that the effect of resisting the increase in threshold gain of lasing at wavelength far from the central wavelength may be achieved.

The above-described case will be described by using a result of calculation shown in FIG. 6.

The result of calculation shown in FIG. 6 is a calculation of the wavelength variable surface light-emitting laser according to the embodiment which is designed so that the wavelength becomes variable around the central wavelength of 850 nm. In the wavelength variable surface light-emitting laser according to the embodiment, which is similar to that illustrated in FIG. 1, variations in threshold gain in a case where the ratio of the thicknesses of the upper space portion and the lower space portion was calculated while maintaining the total thickness of the upper space portion and the lower pace portion was maintained constant.

A lateral axis represents the thickness of the upper space portion. A case where the value of the lateral axis is 1 corresponds to a case where the thicknesses of the upper space portion and the lower space portion is 1:1. The closer the value of the lateral axis to “1”, the closer to the upward and downward symmetry, and if smaller than “1”, the thickness of the upper space portion is small, and if larger than “1”, the thickness of the lower space portion is small.

A vertical axis represents how many folds the threshold gain at a wavelength of 800 nm is in comparison with the threshold gain at a central wavelength of 850 nm. It can be said that the closer the value of the vertical axis to “1”, the less probability of increase in threshold gain even at wavelength far from the central wavelength.

When reviewing the result of calculation shown in FIG. 11, the threshold gain at a wavelength of 800 nm is approximately 1.21 times a wavelength at a wavelength of 850 nm. The threshold gain of the related art is shown by a dot line in FIG. 6. The value of the lateral axis is below the dot line in a range from 0.7 to 1.3, it is understood that the increase in threshold gain is suppressed in comparison with the structure of the related art.

In other words, the range in which the effect of this disclosure is obtained can be said to be a range in which the ratio between the first distance and the second distance is within a range of ±25% from a certain value.

Further, the value becomes not higher than 1.15 in a range in which the value of the vertical axis falls within a range of ±20% in value of the lateral axis.

In the wavelength variable surface light-emitting laser according to the embodiment, the ratio between the first distance and the second distance to be kept constant may be an integer ratio. In particular, if the phase variation when the light reflects on the upper and lower reflectors becomes “0” or “π”, the integer ratio may be employed. It is also possible that the ratio between the first distance and the second distance becomes 1:2 or 2:1.

In the wavelength variable surface light-emitting laser according to the embodiment, a technology generally used in the MEMS field may be used as a device for displacing the reflector or the active layer in the vertical direction. For example, static electricity, piezoelectricity, heat, electromagnet, fluid pressure and the like may be used.

The wavelength variable surface light-emitting laser according to the embodiment, may further include a photoexcitation unit which put light into the active layer in order to cause the active layer to emit light, or a power source configured to infuse an electric current into the active layer. The wavelength variable surface light-emitting laser according to the embodiment, light emission may be achieved by photoexcitation which does not require to consider the arrangement of electrodes or wiring because the positions of at least two elements selected from a group including the upper reflector, the lower reflector, and the active layer are changed.

The wavelength variable surface light-emitting laser according to the embodiment may be used as a light source for an OCT (optical coherence tomographic imaging apparatus) or the like configured to obtain tomographic images of a tested object on the basis of light that is combination of a return light beam from the tested object irradiated with a measurement light beam and reference light beam corresponding to the measurement light beam. Detailed description about the OCT will be described later.

It is also possible to arrange the wavelength variable surface light-emitting lasers according to the embodiment in a plurality of rows on the same plane and use the wavelength variable surface light-emitting lasers as an array light source.

### Optical Coherence Tomographic Imaging Apparatus

The optical coherence tomographic imaging apparatus (hereinafter, it may be abbreviated as OCT) using the wavelength variable light source does not use a spectroscope, and hence obtainment of a cross-sectional imaging with the SN ratio with less loss of light amount is expected.

An example in which the wavelength variable surface light-emitting laser of the embodiment is used for the light source unit for the OCT will be described with reference to FIG. 13.

An OCT apparatus 13 of the embodiment includes at least a light source unit 1301, an interference optical system 1302, a light detecting unit 1303, and an information obtaining unit 1304, and the above-described wavelength variable surface light-emitting laser may be used as the light source unit 1301. Although not illustrated, the information obtaining unit 1304 includes a Fourier transformer. Here, “the information obtaining unit 1304 includes the Fourier transformer” is not limited specifically as long as the information obtaining unit has a function to perform Fourier transformation on input data. An example is a case where the information obtaining unit 1304 is a computer including a calculating unit, and the calculating unit has a function to perform the Fourier transformation. Specifically, it is a case where the calculating unit is a computer having a CPU, and the computer executes an application having a function to perform the Fourier transformation. Another example is a case where the information obtaining unit 1304 include a Fourier transformation circuit having a function to perform the Fourier transformation. Light outgoing from the light source unit 1301 passes through the interference optical system 1302 and is output as an interfering light beam having information on a substance 1312 as an object to be measured. The interfering light beam is received by the light detecting unit 1303. The light detecting unit 1303 may be of a differential detecting type or of a simple intensity monitoring type. Information on temporal waveform of the intensity of the received interfering light beam is sent from the light detecting unit 1303 to the information obtaining unit 1304. The information obtaining unit 1304 obtains a peak value of the temporal waveform having the intensity of the received interfering light beam and performs the Fourier transformation to obtain information on the substance 1312 (for example, information on the cross-sectional imaging). The light source unit 1301, the interference optical system 1302, the light detecting unit 1303, and the information obtaining unit 1304 may be provided arbitrarily.

An operation from emission of light from the light source unit 1301 until an obtainment of the information on the cross-sectional imaging of a substance will now be described in detail below.

Light outgoing from the light source unit 1301 configured to vary the wavelength of the light passes through a fiber 1305, enters a coupler 1306, and is split into an illuminated light beam passing through a fiber 1307 for the illuminated light beam and an illuminated light beam passing through a fiber 1308 for the reference light beam. The coupler 1306 may be a coupler operated in a single mode in a band of wavelength of the light source, and the respective fiber couplers may be 3 dB couplers. The illuminated light beam becomes a parallel light beam by passing through a collimator 1309, and is reflected by a mirror 1310. The light reflected by the mirror 1310 passes through a lens 1311 and is radiated on the substance 1312, and is reflected by respective layers in the direction of the depth of the substance 1312. In contrast, the reference light beam passes through a collimator 1313 and is reflected by a mirror 1314. In the coupler 1306, an interfering light beam caused by a reflected light beam from the substance 1312 and an interfering light beam caused by a reflecting light beam from the mirror 1314 is generated. The interfered light passes through a fiber 1315, is condensed through a collimator 1316, and is received by the light detecting unit 1303. Information on intensity of the interfering light beam received by the light detecting unit 1303 is converted into electric information such as voltage, and is sent to the information obtaining unit 1304. The information obtaining unit 1304 processes, more specifically, performing the Fourier transformation of the data of the intensity of the interfering light beam, so that information of the cross-sectional imaging is obtained. The data of the intensity of the interfering light beam to be subjected to the Fourier transformation is normally data sampled at uniform frequency spacing. However, data sampled at uniform wavelength spacing may also be used.

The information on the obtained cross-sectional imaging may be sent from the information obtaining unit 1304 to the image display unit 1317, and displayed as an image. By scanning with the mirror 1310 in a plane vertical to the plane perpendicular to the direction of the incident illuminated light beam, a three-dimensional cross-sectional imaging of the substance 1312 is obtained. Control of the light source unit 1301 may be performed by the information obtaining unit 1304 via an electric circuit 1318. Although not illustrated, the intensity of light outgoing from the light source unit 1301 is monitored in sequence, and the data therefrom may be used for correcting the amplitude of an intensity signal of the interfering light beam.

The OCT apparatus according to the embodiment is effective when obtaining a cross-sectional imaging of biological bodies such as animals or human being in departments of ophthalmology, dentistry, and dermatology. Information on the cross-sectional imaging of the biological bodies includes not only the cross-sectional imaging of the biological bodies, but also numerical data required for obtaining the cross-sectional imaging.

It is to be used for measuring an eyeground of human being as an object to be measured, and obtaining information on the cross-sectional imaging of the eyeground.

### Other Applications

The wavelength variable surface light-emitting laser of this disclosure may be used as an optical communication light source or as an optical measurement light source in addition to the above-described OCT.

### EXAMPLES

Examples of this disclosure will be described. This disclosure is not limited to configurations of Examples which will be described blow. For example, the type, composition, shape and size of the material may be changed as needed within the scope of this disclosure.

In the following Examples, a lasing wavelength near 850 nm is described. However, operations at arbitrary wavelengths are also possible by selecting adequate materials and structures.

### Example 1

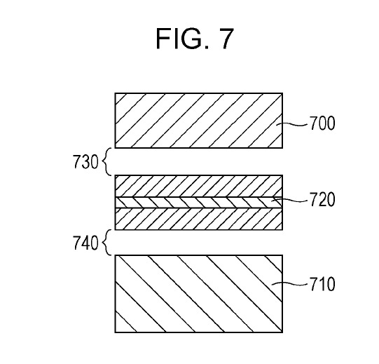

An example of the configuration of the VCSEL including a distribution Bragg reflector is employed as the reflector to which this disclosure is applied will be described as Example 1 with reference to FIG. 7. FIG. 7 is a schematic cross-sectional view illustrating a layer structure of the VCSEL according to Example 1.

The VCSEL of this example is designed so as to allow a wavelength sweeping at a central wavelength of 850 nm.

An upper reflector 700, an upper space portion 730, an active layer 720, a lower space portion 740, and a lower reflector 710 are arranged in this order from the top.

The thicknesses of the upper space portion 730 and the lower space portion 740 are equal, and the upper reflector 700 and the lower reflector 710 are arranged with the active layer 720 interposed therebetween at the same distance.

The cavity length is configured to correspond to two wavelengths when a central wavelength of 850 nm is defined as one wavelength.

The upper reflector is a DBR formed by stacking five pairs of Al_{0.15}Ga_{0.85}As and oxidized AlAs alternately, and has a thickness of approximately 900 nm.

The lower reflector is a DBR formed by stacking seven pairs of Al_{0.15}Ga_{0.85}As and oxidized AlAs alternately, and has a thickness of approximately 1260 nm.

The active layer is formed of In_{0.08}Ga_{0.92}As having a thickness of 8 nm. The upper and lower reflectors are configured to be varied in position in the vertical direction by electrostatic force generated by an application of voltage.

At this time, the thicknesses of the upper space portion and the lower space portion are controlled to be the same.

The lasing wavelength can be shifted toward the short wavelength side by lasing at a wavelength of 850 nm when the thickness of the upper and lower space portions are 210 nm and setting the upper and lower space portions to be thinner than 210 nm, and can be shifted toward the long wavelength side by setting to be thicker than 210 nm.

The space portion of this example is formed by using an epitaxial growth and selected wet etching. An outline of the procedure will be described.

When performing the epitaxial growth, portion corresponding to the space portion is formed with a film of GaAs as a sacrifice layer.

By using compound liquid including water, citric acid, and hydrogen peroxide solution as etchant, the selected etching according to the Al composition of AlGaAs is achieved. In this example, mixture of citric acid solution prepared by mixing water and citric acid (weight ratio 1:1) and hydrogen peroxide solution having a concentration of 30% by a ratio of 2:1 is used as the etchant. At this concentration, the selected etching of GaAs, Al_{0.15}Ga_{0.85}As is enabled, so that the space portion can be formed only by removing the GaAs sacrifice layer.

In a configuration of this example, variation in threshold gain when sweeping the lasing wavelength from 850 nm to 800 nm is 1.12 times.

### Example 2

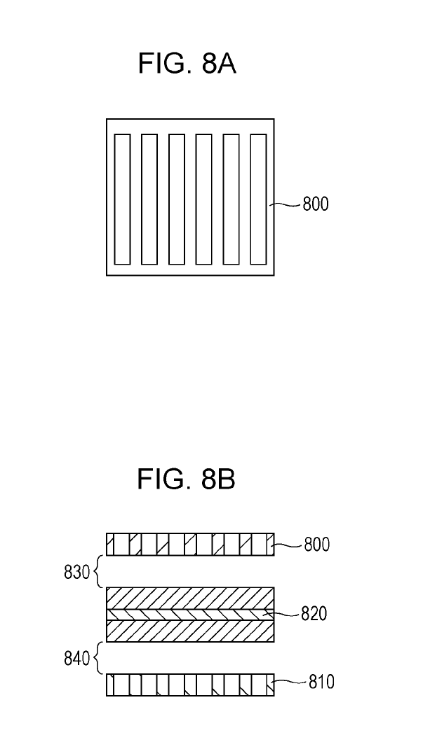

A configuration example of the VCSEL in which at least one of the reflectors to which this disclosure is applied is a diffraction grating will be described as Example 2 with reference to FIG. 8.

The VCSEL of this example is designed so as to allow a wavelength sweeping at a central wavelength of 850 nm.

The point of Example 2 different from Example 1 is that the upper reflector is composed of a diffraction grating having a periodic structure of a sub-wavelength referred to as HCG (High-Contrast Grating). Other portions are the same as those of Example 1.

FIG. 8A is an upper schematic drawing of the HCG structure used as an upper reflector 800. FIG. 8B is a schematic cross-sectional view illustrating a layer structure of the VCSEL according to Example 2. The upper reflector 800 includes an Al_{0.7}Ga_{0.3}As layer having a thickness of 250 nm and the HCG including grooves having a width of 137 nm formed cyclically at every 390 nm. A lower reflector 810 also includes an HCG which is similar to that of the upper reflector 800.

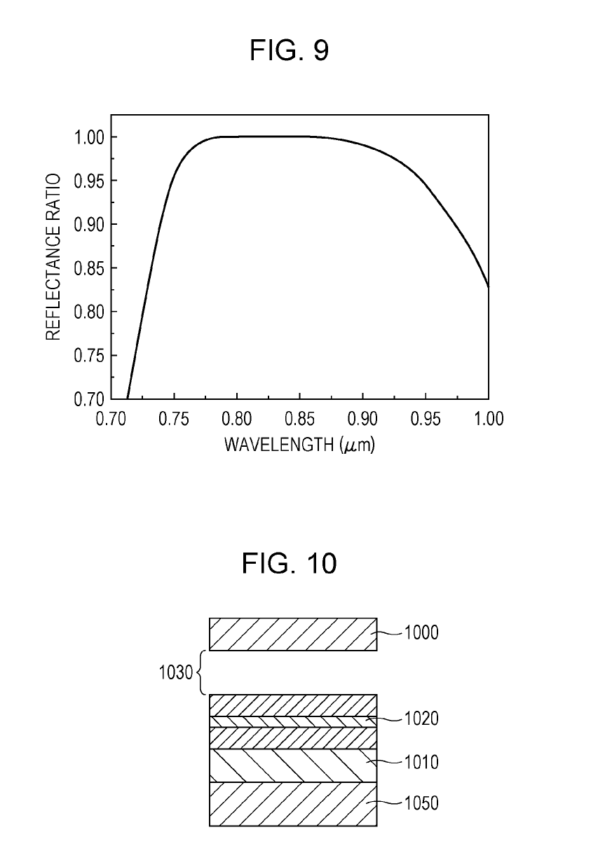

FIG. 9 shows a result of calculation of the reflectance ratio of the HCG in Example will be described. A reflectance ratio near 100% is obtained around a wavelength of 850 nm.

A width of the wavelength from which the reflectance ratio of 99% or higher is obtained is approximately 135 nm, and high reflectance ratios are obtained in a very wide wavelength range.

A benefit in using the HCG as the reflector as in Example 2 is that a high reflectance ratio is obtained with a thinner layer in comparison with a DBR or the like, and a wavelength range from which a high reflectance ratio is obtained is wide.

If the reflector is tin and light, high-speed vibrations (displacement) are possible, and is effective for increasing the wavelength seeping speed.

A large wavelength range from which a high reflectance ratio is obtained may lead to widening of the wavelength range in which the wavelength sweeping can be performed.

Therefore, the configuration in which the HCG is used as the reflector as in Example 2 can be said to be a configuration suitable for the wavelength sweeping at a high speed and in a large bandwidth.

According to this disclosure, a surface light-emitting laser capable of restraining an increase in threshold gain of lasing at wavelengths far from the central wavelength is achieved.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-169607 filed Aug. 19, 2013, which is hereby incorporated by reference herein in its entirety.

What is claimed is:

1. A laser comprising an upper reflector, a lower reflector, and an active layer interposed therebetween, wherein when an optical distance between the upper reflector and the lower reflector is referred to as a first distance, and an optical distance between the lower reflector and the active layer is referred to as a second distance,
positions of at least selected two of a group including the upper reflector, the lower reflector, and the active layer are changed so that a ratio between the first distance and the second distance is maintained within a range of ±25% from a certain value.

2. The laser according to claim 1, wherein the ratio between the first distance and the second distance is configured to be kept within a range of ±20% from a certain value.

3. The laser according to claim 1, wherein the ratio between the first distance and the second distance is kept within a range of ±5% from a certain value.

4. The laser according to claim 1, wherein the upper reflector and the lower reflector are displaced at a same cycle and in opposite phases.

5. The laser according to claim 1, wherein the ratio between the first distance and the second distance is configured to be kept as an integer ratio.

6. The laser according to claim 1, wherein the upper reflector and the lower reflector are displaced at same amplitude, and the active layer is arranged at a central position between the upper reflector and the lower reflector.

7. The laser according to claim 1, wherein the ratio between the first distance and the second distance is 1:2 or 2:1.

8. The laser according to claim 1, further comprising a photoexcitation unit which put light into the active layer in order to cause the active layer to emit light, or a power source configured to infuse an electric current into the active layer.

9. The laser according to claim 1, wherein at least one of the upper reflector and the lower reflector includes a distribution Bragg reflector.

10. The laser according to claim 1, wherein at least one of the upper reflector and the lower reflector includes a diffraction grating.

11. An apparatus comprising:
a light source unit configured to vary a wavelength of light;
an optical system configured to split light from the light source unit into an illuminated light beam to be radiated on an object and a reference light beam to cause a reflected light of the light beam radiated on the object and an interfering light beam caused by the reference light beam to be generated,
a detecting unit configured to receive the interfering light beam, and
an obtaining unit configured to process a signal from the detecting unit and obtain information on the object,
wherein the light source unit is the laser according to claim 1.

12. The apparatus according to claim 11, wherein the ratio between the first distance and the second distance is configured to be kept within a range of ±20% from a certain value.

13. The apparatus according to claim 11, wherein the ratio between the first distance and the second distance is kept within a range of ±5% from a certain value.

14. The apparatus according to claim 11, wherein the upper reflector and the lower reflector are displaced at a same cycle and in opposite phases.

15. The apparatus according to claim 11, wherein the ratio between the first distance and the second distance is configured to be kept as an integer ratio.

16. The apparatus according to claim 11, wherein the upper reflector and the lower reflector are displaced at same amplitude, and the active layer is arranged at a central position between the upper reflector and the lower reflector.

17. The apparatus according to claim 11, wherein the ratio between the first distance and the second distance is 1:2 or 2:1.

18. The apparatus according to claim 11, further comprising a photoexcitation unit which put light into the active layer in order to cause the active layer to emit light, or a power source configured to infuse an electric current into the active layer.

19. The apparatus according to claim 11, wherein at least one of the upper reflector and the lower reflector includes a distribution Bragg reflector.

20. The apparatus according to claim 11, wherein at least one of the upper reflector and the lower reflector includes a diffraction grating.
